(19) United States
(12) Patent Application Publication
(10) Pub. No.: US 2014/0272187 A1
(43) Pub. Date: Sep. 18, 2014

(54) ADHESION IMPROVEMENT BETWEEN CVD DIELECTRIC FILM AND CU SUBSTRATE

(71) Applicant: Applied Materials, Inc., Santa Clara, CA (US)

(72) Inventors: Tae Kyung WON, San Jose, CA (US); Yi CUI, San Jose, CA (US); Beom Soo PARK, San Jose, CA (US); Soo Young CHOI, Fremont, CA (US)

(21) Appl. No.: 14/180,339

(22) Filed: Feb. 13, 2014

Related U.S. Application Data
(60) Provisional application No. 61/788,852, filed on Mar. 15, 2013.

(51) Int. Cl. C23C 16/02; C23C 16/34

(52) U.S. Cl. CPC C23C 16/0281; C23C 16/345; C23C 16/0227
USPC 427/535

(57) ABSTRACT

Methods of forming dielectric layers on a copper substrate are disclosed herein. In one embodiment, a method of depositing a dielectric layer can include positioning a copper substrate in a process chamber, forming and delivering the cleaning plasma to the substrate to form a cleaned surface on the substrate, forming and delivering the adhesion plasma to the surface of the substrate to form a copper compound thereon and depositing a dielectric layer over the copper compound. In another embodiment, a method of depositing a dielectric layer can include positioning a copper substrate in a process chamber, delivering an adhesion plasma to the copper substrate to form a copper compound and flowing a deposition gas into the process chamber to deposit a dielectric layer over the copper compound, wherein the flow between the adhesion plasma and the deposition gas is continuous.

### CROSS-REFERENCE TO RELATED APPLICATIONS

This application claims benefit of U.S. Provisional Patent Application Ser. No. 61/788,852, filed Mar. 15, 2013, which is herein incorporated by reference.

### BACKGROUND OF THE INVENTION

1. Field of the Invention

Embodiments described herein generally relate to dielectric film adhesion to copper.

2. Description of the Related Art

Integrated circuit devices generally incorporate conductive metals, such as copper. Copper provides numerous benefits over other conductive metals. The conductivity of copper is approximately twice that of aluminum and over three times that of tungsten. As a result, the same current can be carried through a copper line having half the width of an aluminum line. Aluminum is approximately ten times more susceptible than copper to degradation and breakage through electromigration.

In some instances, the substrate can be composed entirely of copper with one or more layers formed thereon. However, peeling of these layers, such as dielectric thin films, creates a problem when creating features or devices on the copper substrate. One technique to enhance adhesion includes roughening the surface prior to initial deposition. However, surface roughening creates problems in conformality while not completely solving the problem of adhesion.

Therefore, there is a need in the art for better methods of increasing adhesion to copper.

### SUMMARY OF THE INVENTION

The embodiments described herein generally relate to depositing dielectric films on copper. In one embodiment, a method of depositing a dielectric layer can include positioning a copper substrate in a process chamber, forming a cleaning plasma from a cleaning gas, delivering the cleaning plasma to the substrate to form a cleaned surface on the substrate, forming an adhesion plasma from a compound-forming gas, delivering the adhesion plasma to the surface of the substrate to form a copper compound thereon and depositing a dielectric layer over the copper compound.

In another embodiment, a method of depositing a dielectric layer can include positioning a copper substrate in a process chamber, delivering an adhesion plasma to the copper substrate to at least form a copper compound on the surface of the substrate, wherein the adhesion plasma comprises at least one compound-forming gas and flowing a deposition gas into the process chamber to deposit a dielectric layer over the copper compound by chemical vapor deposition, wherein the flow between the adhesion plasma and the deposition gas is continuous.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings.

It is to be noted, however, that the appended drawings illustrate only typical embodiments of this invention and are therefore not to be considered limiting of its scope, for the invention may admit to other equally effective embodiments.

FIG. 1 a cross-sectional view of a process chamber according to one embodiment of the invention;

FIG. 2A-2C depict a substrate processed according to one embodiment; and

FIG. 3 is a flow diagram of a method for depositing a dielectric layer on a copper substrate according to one embodiment.

To facilitate understanding, identical reference numerals have been used, where possible, to designate identical elements that are common to the figures. It is contemplated that elements disclosed in one embodiment may be beneficially utilized on other embodiments without specific recitation.

### DETAILED DESCRIPTION

Though copper substrates are important to the production of various integrated circuit devices, adherence of deposited layers is a continual problem. In embodiments described herein plasma treatment of the substrate is used to enhance adhesion to the surface and allow subsequent deposition of one or more layers. The plasma treatment includes an initial treatment of the copper substrate with a precleaning plasma which can form a copper compound on the surface of the copper substrate. The precleaning plasma can be continuous with the deposition of the dielectric layer. By forming a copper compound on the surface of the copper substrate continuously with deposition of a dielectric layer, adhesion of the dielectric layer can be enhanced. The embodiments disclosed herein are more clearly described with reference to the figures below.

The invention is illustratively described below utilized in a processing system, such as a plasma enhanced chemical vapor deposition (PECVD) system available from AKT America, a division of Applied Materials, Inc., located in Santa Clara, Calif. However, it should be understood that the invention has utility in other system configurations, including those sold by other manufacturers.

FIG. 1 is a schematic, cross sectional view of a process chamber that may be used to perform the operations described herein. The apparatus includes a chamber 100 in which one or more films may be deposited onto a substrate 120. The chamber 100 generally includes walls 102, a bottom 104 and a showerhead 106 which define a process volume. A substrate support 118 is disposed within the process volume. The process volume is accessed through a slit valve opening 108 such that the substrate 120 may be transferred in and out of the chamber 100. The substrate support 118 may be coupled to an actuator 116 to raise and lower the substrate support 118. Lift pins 122 are moveably disposed through the substrate support 118 to move a substrate to and from the substrate receiving surface. The substrate support 118 may also include heating and/or cooling elements 124 to maintain the substrate support 118 at a desired temperature. The substrate support 118 can also include RF return straps 126 to provide an RF return path at the periphery of the substrate support 118.

The showerhead 106 can be coupled to a backing plate 112 by a fastening mechanism 140. The showerhead 106 may be coupled to the backing plate 112 by one or more fastening mechanisms 140 to help prevent sag and/or control the straightness/curvature of the showerhead 106.

A gas source 132 can be coupled to the backing plate 112 to provide process gases through gas passages in the showerhead 106 to a processing area between the showerhead 106 and the substrate 120. The gas source 132 can include a silicon-containing gas supply source, an oxygen containing gas supply source, and a carbon-containing gas supply source, among others. Typical process gases useable with one or more embodiments include silane (SiH₄), disilane, N₂O, ammonia (NH₃), H₂, N₂ or combinations thereof.

A vacuum pump 110 is coupled to the chamber 100 to control the process volume at a desired pressure. An RF source 128 can be coupled through a match network 150 to the backing plate 112 and/or to the showerhead 106 to provide an RF current to the showerhead 106. The RF current creates an electric field between the showerhead 106 and the substrate support 118 so that a plasma may be generated from the gases between the showerhead 106 and the substrate support 118.

A remote plasma source 130, such as an inductively coupled remote plasma source 130, may also be coupled between the gas source 132 and the backing plate 112. Between processing substrates, a cleaning gas may be provided to the remote plasma source 130 so that a remote plasma is generated. The radicals from the remote plasma may be provided to chamber 100 to clean chamber 100 components. The cleaning gas may be further excited by the RF source 128 provided to the showerhead 106.

The showerhead 106 may additionally be coupled to the backing plate 112 by showerhead suspension 134. In one embodiment, the showerhead suspension 134 is a flexible metal skirt. The showerhead suspension 134 may have a lip 136 upon which the showerhead 106 may rest. The backing plate 112 may rest on an upper surface of a ledge 114 coupled with the chamber walls 102 to seal the chamber 100.

FIGS. 2A-2C are schematic illustrations of a copper substrate processed according to one embodiment. In FIG. 2A, a substrate 202 can be positioned in a process chamber, such as the process chamber depicted in FIG. 1. In one embodiment, the substrate 202 is made entirely of copper. Formed on the surface of the substrate 202 is an oxide layer 204. The oxide layer 204 forms based on contact with the atmosphere, such as during transfer between chambers. The substrate 202 receives a cleaning plasma 206. The cleaning plasma 206 can include an inert gas, such as argon, or another gas such as hydrogen. The cleaning plasma 206 can be created using RF or microwave sources.

In FIG. 2B, the substrate 202 is depicted as having the oxide layer 204 removed. The cleaned surface of the substrate 202 then receives an adhesion plasma 208. The adhesion plasma 208 can be a plasma formed from a number of compound-forming gases including hydrogen (H₂), phosphine (PH₃), nitrogen trifluoride (NF₃), silane (SiH₄), ammonia (NH₃), oxygen (O₂) or other gases. The adhesion plasma 208 can also be a plasma formed from a second gas to which the compound-forming gas is added, such as argon. The adhesion plasma 206 can be created using RF or microwave sources. The adhesion plasma 206 can form one or more copper compounds on the cleaned surface. The copper compounds can include copper hydrides, copper silicides, copper fluoride, copper oxide, copper nitride, combinations thereof or permutations thereof.

In one or more embodiments, the cleaning plasma 206 comprises the same gas or gases as the adhesion plasma 208. As such, the adhesion plasma 208 can be used in place of or in addition to the cleaning plasma 206.

As shown in FIG. 2C, after the copper compound is formed on the surface, a deposition gas 212 can be delivered to the substrate 202. The deposition gas 212 then forms a dielectric layer 210 over the exposed portion of the surface of the substrate. The dielectric layer 210 can include SiOF, SiN, SiOx, and silicon oxynitride (SiON). Additionally, while shown as a single layer, it is contemplated that the dielectric layer 210 may comprise multiple layers, each of which may comprise a different chemical composition. Suitable methods for depositing the dielectric layer 210 include deposition methods such as MW-PECVD, PECVD, CVD and atomic layer deposition (ALD). In one embodiment, the dielectric layer 210 is composed of SiN deposited by MW-PECVD. In this embodiment, the dielectric layer 210 has an adhesion peel strength of greater than 0.4 kgF/cm². In one embodiment, the dielectric layer 210 has an adhesion peel strength of greater than 1.0 kgF/cm². In another embodiment, the dielectric layer 210 has an adhesion peel strength of greater than 1.5 kgF/cm².

FIG. 3 is a flow diagram of a method 300 for depositing a dielectric layer on a copper substrate according to one embodiment. The method 300 begins with positioning a copper substrate in a process chamber, as in step 302. The substrate and the process chamber can be the substrate and process chamber as described above. Various sizes of copper substrate can be used, based on the needs of the device and the end user.

Optionally, a cleaning plasma can then be formed from a cleaning gas, as in step 304. In one embodiment, the cleaning gas is an inert gas, such as argon, helium or other noble gas. In another embodiment, the cleaning gas can comprise NH₃ or H₂. The cleaning gas can be formed into a plasma using an RF or microwave source. Further, the cleaning gas can be formed either in the process chamber or remotely.

If the cleaning plasma is formed, the cleaning plasma can then be delivered to the substrate to form a cleaned surface on the substrate, as in step 306. When a substrate, such as a copper substrate, is transferred between chambers, it can accumulate oxygen and moisture from the atmosphere. The oxygen and moisture can then form compounds on the surface of the substrate, which can interfere with adherence on the surface or properties of the substrate generally. By delivering the cleaning plasma to the substrate, the surface can be cleaned for subsequent processing.

An adhesion plasma is then formed from a compound-forming gas, as in step 308. The compound forming gas can be a gas selected from the gases listed in relation to FIG. 2. Similar to the cleaning gas, the adhesion gas can be formed into a plasma using an RF or microwave source. Further, the adhesion gas can be formed either in the process chamber or remotely.

The adhesion plasma is then delivered to the surface of the substrate to form a copper compound thereon, as in step 310. In the absence of the cleaning plasma, the adhesion plasma provides both a cleaning and a compound forming function. Copper compounds can include the compounds described with reference to FIG. 2.

Without intending to be bound by theory, the compounds formed by atmospheric conditions are largely indiscriminate across the surface of the copper substrate and are formed from a variety of available reactants. As such, these compounds can inhibit proper adhesion of subsequent layers to the surface. However, deposited layers, such as dielectric layers, fail to properly adhere to the cleaned surface as well, due to what is believed to be inherent properties in the copper substrate. By forming a copper compound on the surface of the substrate with the adhesion forming plasma, adherence of subsequent layers, such as dielectric layers, is increased.

A dielectric layer is then deposited over the copper compound, as in step 312. The dielectric layer can be deposited using various deposition gases or combinations thereof, such as silane, disilane, methane, H₂, N₂, NH₃, O₂ or other gases. Though deposition of the dielectric layer is primarily described as employing PECVD, the dielectric layer can be deposited by various means such as PVD, CVD, PECVD or other methods. The dielectric layer can comprise various silicon or carbon containing compounds, e.g. SiOF, SiN, SiOx, SiON and silicon carbide (SiC).

The adhesion plasma can be delivered to the surface of the substrate in a continuous fashion. Stated another way, the adhesion plasma can be delivered to the substrate without a separation between the adhesion plasma, the cleaning plasma, the deposition gas plasma or combinations thereof. Without intending to be bound by theory, it is believed that by maintaining a continuous flow, compounds formed on the copper substrate are highly energetic during the plasma treatment and therefore both more mobile and more reactive. As such, by depositing the compounds consecutively, intermediate compounds may be formed at the interface between the copper compound and the dielectric layer. These intermediate compounds act as a scaffold for subsequent deposition of the dielectric layer.

In one exemplary embodiment, a copper substrate was precleaned using a plasma comprising NH₃ for 50 seconds to both clean the surface and deposit copper nitrides on the exposed surface. The plasma was maintained and a SiN layer was deposited using silane and a nitrogen containing precursor to a targeted thickness of 200 nm (50 seconds). The substrate was maintained at a temperature of 154° C. for the preclean and 149° C. for the deposition step. The deposited film had a film stress of 460 Mpa and an adhesion peel strength of greater than 0.4 kgF/cm².

In another embodiment, a copper substrate was precleaned using a plasma comprising NH₃ for 70 seconds to both clean the surface and deposit copper nitrides on the exposed surface. The plasma was maintained and a SiN layer was partially deposited using silane and a nitrogen containing precursor for 10 seconds. The substrate was allowed to cool for 10 minutes before the plasma was re-ignited and a SiN layer was deposited using silane and a nitrogen containing precursor for 40 seconds and to a total thickness of 200 nm. The substrate was maintained at a temperature of 149° C. The deposited film had a film stress of 460 Mpa and an adhesion peel strength of greater than 0.4 kgF/cm².

In another embodiment, a copper substrate was precleaned using a plasma comprising NH₃ for 80 seconds. The substrate was allowed to cool for 10 minutes prior to further treatment with plasma comprising H₂ for 50 seconds. The plasma was maintained and a SiN layer was deposited using silane and a nitrogen containing precursor to a targeted thickness of 200 nm (50 seconds). The substrate was maintained at a temperature of 138° C. The deposited film had a film stress of 50 Mpa and an adhesion peel strength of greater than 0.5 kgF/cm².

Embodiments described herein relate to the formation of a dielectric layer on a copper substrate. Dielectric layers formed over copper have poor adhesion even on cleaned copper. By pretreating the copper to form a copper compound prior to the formation of the dielectric layer, adhesion can be increased. Thus, by increasing adhesion of the dielectric layer, subsequent features can be formed on a copper substrate. Further embodiments can include continuous plasma between the precleaning/adhesion plasma and the deposition of the dielectric layer. The formation of the copper compounds and the seamless transition to deposition provides further benefits to adherence between the copper substrate and the dielectric layer deposited thereon.

While the foregoing is directed to embodiments of the present invention, other and further embodiments of the invention may be devised without departing from the basic scope thereof, and the scope thereof is determined by the claims that follow.

What is claimed is:

1. A method of depositing a dielectric layer comprising:
positioning a copper substrate in a process chamber;
forming a cleaning plasma from a cleaning gas;
delivering the cleaning plasma to the substrate to form a cleaned surface on the substrate;
forming an adhesion plasma from a compound-forming gas;
delivering the adhesion plasma to the surface of the substrate to form a copper compound thereon; and
depositing a dielectric layer over the copper compound.

2. The method of claim 1, wherein the dielectric layer is a silicon nitride layer.

3. The method of claim 1, wherein the dielectric layer is deposited by plasma enhanced chemical vapor deposition (PECVD).

4. The method of claim 3, wherein the PECVD is either capacitive coupled plasma (CCP)-PECVD or microwave (MW)-PECVD.

5. The method of claim 1, wherein the compound-forming gas comprises a gas selected from hydrogen (H₂), phosphine (PH₃), nitrogen trifluoride (NF₃), silane (SiH₄), ammonia (NH₃), oxygen (O₂) or combinations thereof.

6. The method of claim 1, wherein the compound forming gas comprises two or more gases.

7. The method of claim 1, further comprising delivering a second adhesion plasma to the surface of the substrate after delivering the adhesion plasma.

8. A method of depositing a dielectric layer comprising:
positioning a copper substrate in a process chamber;
delivering an adhesion plasma to the copper substrate to at least form a copper compound on the surface of the substrate, wherein the adhesion plasma comprises at least one compound-forming gas; and
flowing a deposition gas into the process chamber to deposit a dielectric layer over the copper compound by chemical vapor deposition, wherein the flow between the adhesion plasma and the deposition gas is continuous.

9. The method of claim 8, wherein the dielectric layer is a silicon nitride layer.

10. The method of claim 8, wherein the dielectric layer is deposited by plasma enhanced chemical vapor deposition.

11. The method of claim 10, wherein the PECVD is either capacitive coupled plasma (CCP)-PECVD or microwave (MW)-PECVD.

12. The method of claim 8, wherein the compound-forming gas comprises a gas selected from hydrogen (H₂), phosphine (PH₃), nitrogen trifluoride (NF₃), silane (SiH₄), ammonia (NH₃), oxygen (O₂) or combinations thereof.

13. The method of claim 8, wherein the compound forming gas comprises two or more gases.

14. The method of claim 7, further comprising delivering a second adhesion plasma to the surface of the substrate after delivering the adhesion plasma.

15. A method of depositing a dielectric layer comprising:
precleaning a substrate in a processing region of a processing chamber, the substrate comprising copper;
forming an plasma using an adhesion gas in the processing region, the adhesion gas comprising a compound-forming gas;
delivering the adhesion plasma to the substrate to at least form a copper compound on the surface of the substrate;
transitioning the adhesion gas to a deposition gas, wherein the plasma is maintained; and
depositing a dielectric layer over the copper compound by plasma enhanced chemical vapor deposition, wherein the flow between the adhesion plasma and the deposition gas is continuous.

16. The method of claim 15, wherein the dielectric layer comprises SiOF, SiN, SiOx, or silicon oxynitride (SiON).

17. The method of claim 16, wherein the dielectric layer is a silicon nitride layer.

18. The method of claim 15, wherein the PECVD is either capacitive coupled plasma (CCP)-PECVD or microwave (MW)-PECVD.

19. The method of claim 15, wherein the compound-forming gas comprises a gas selected from hydrogen (H₂), phosphine (PH₃), nitrogen trifluoride (NF₃), silane (SiH₄), ammonia (NH₃), oxygen (O₂) or combinations thereof.

20. The method of claim 15, wherein precleaning the substrate comprises forming a cleaning plasma comprising an inert gas.
